(19) United States
(12) Patent Application Publication
(10) Pub. No.: US 2025/0261518 A1
(43) Pub. Date: Aug. 14, 2025

(54) DISPLAY DEVICE

(71) Applicant: Japan Display Inc., Tokyo (JP)

(72) Inventors: Hideyuki TAKAHASHI, Tokyo (JP); Takamitsu FUJIMOTO, Tokyo (JP); Hiroshi TABATAKE, Tokyo (JP); Sho YANAGISAWA, Tokyo (JP)

(73) Assignee: Japan Display Inc., Tokyo (JP)

(21) Appl. No.: 19/038,716

(22) Filed: Jan. 28, 2025

(30) Foreign Application Priority Data
Feb. 14, 2024 (JP) 2024-020336

(51) Int. Cl. H10K 59/122; H10K 59/131; H10K 59/80

(52) U.S. Cl. CPC H10K 59/122; H10K 59/131; H10K 59/873

(57) ABSTRACT

According to one embodiment, a display device includes a substrate having a display and a surrounding area, display elements in the display area, each of the display elements including a lower electrode, an upper electrode, and an organic layer, a first partition provided in the display area and provided between the adjacent display elements, and a second partition provided in the surrounding area and connected to the first partition. Each of the first and second partitions includes a conductive lower portion and an upper portion which has an end portion protruding from a side surface of the lower portion. Further, the second partition has apertures each of which has an elongated shape.

### CROSS-REFERENCE TO RELATED APPLICATIONS

This application is based upon and claims the benefit of priority from Japanese Patent Application No. 2024-020336, filed Feb. 14, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique which can improve the yield and reliability is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of the display device along the III-III line of FIG. 2.

FIG. 4 is a schematic plan view of the display device for explaining the structure of a surrounding area.

FIG. 5 is the schematic cross-sectional view of part of the surrounding area along the V-V line of FIG. 4.

FIG. 6 is a schematic enlarged cross-sectional view of part of a partition provided in the surrounding area.

FIG. 7 is a schematic enlarged plan view of area VII of FIG. 4.

FIG. 8 is a schematic enlarged plan view of area VIII of FIG. 4.

FIG. 9A is a schematic cross-sectional view showing an example of the manufacturing process of the display device.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 9H is a schematic cross-sectional view showing a process following FIG. 9G.

FIG. 9I is a schematic cross-sectional view showing a process following FIG. 9H.

FIG. 10 is a schematic plan view of the surrounding area according to a comparative example.

FIG. 11 is a schematic cross-sectional view of the surrounding area according to the above comparative example.

FIG. 12 is a schematic enlarged plan view of a surrounding area according to a second embodiment.

FIG. 13 is another schematic enlarged plan view of the surrounding area according to the second embodiment.

### DETAILED DESCRIPTION

In general, according to one embodiment, a display device comprises a substrate having a display area which displays an image, and a surrounding area around the display area, a plurality of display elements in the display area, each of the display elements including a lower electrode, an upper electrode above the lower electrode, and an organic layer between the lower electrode and the upper electrode and emitting light based on application of voltage, a first partition provided in the display area and provided between the adjacent display elements, and a second partition provided in the surrounding area and connected to the first partition. Each of the first partition and the second partition includes a conductive lower portion and an upper portion which has an end portion protruding from a side surface of the lower portion. Further, the second partition has a plurality of apertures each of which has an elongated shape.

The embodiment can provide a display device which can realize the improvement of the yield or reliability.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

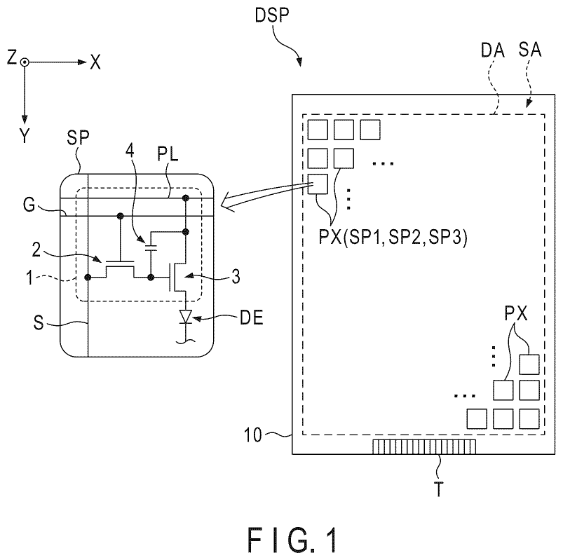

FIG. 1 is a diagram showing a configuration example of a display device DSP according to a first embodiment. The display device DSP comprises an insulating substrate 10. The substrate 10 has a display area DA which displays an image, and a surrounding area SA located around the display area DA. The substrate 10 may be glass or a resinous film having flexibility.

In the embodiment, the substrate 10 and the display area DA are rectangular as seen in plan view. It should be noted that the shape of each of the substrate 10 and the display area DA in plan view is not limited to a rectangle and may be another shape such as a square, a precise circle or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

In the display area DA, a plurality of scanning lines G which supply a scanning signal to the pixel circuit 1 of each subpixel SP, a plurality of signal lines S which supply a video signal to the pixel circuit 1 of each subpixel SP and a plurality of power lines PL are provided. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

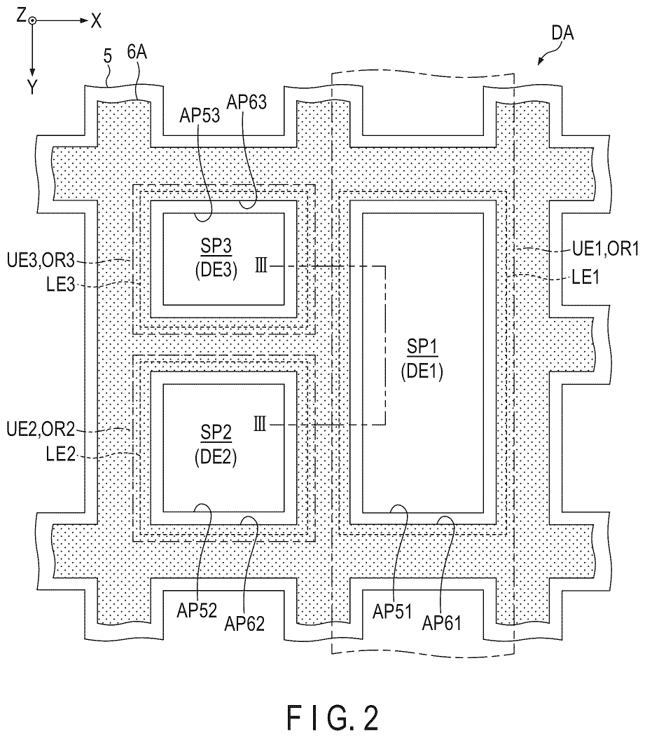

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP51, AP52 and AP53 in subpixels SP1, SP2 and SP3, respectively. In the example of FIG. 2, the pixel aperture AP51 is larger than the pixel aperture AP52. The pixel aperture AP52 is larger than the pixel aperture AP53. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP51. Subpixel SP2 comprises a lower electrode LE2, an upper electrode UE2 and an organic layer OR2 overlapping the pixel aperture AP52. Subpixel SP3 comprises a lower electrode LE3, an upper electrode UE3 and an organic layer OR3 overlapping the pixel aperture AP53.

Of the lower electrode LE1, the upper electrode UE1 and the organic layer OR1, the portions which overlap the pixel aperture AP51 constitute the display element DE1 of subpixel SP1. Of the lower electrode LE2, the upper electrode UE2 and the organic layer OR2, the portions which overlap the pixel aperture AP52 constitute the display element DE2 of subpixel SP2. Of the lower electrode LE3, the upper electrode UE3 and the organic layer OR3, the portions which overlap the pixel aperture AP53 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided on the rib layer 5. The partition 6A overlaps the rib layer 5 as a whole and has a planar shape similar to that of the rib layer 5. In other words, the partition 6A has pixel apertures AP61, AP62 and AP63 in subpixels SP1, SP2 and SP3, respectively. From another viewpoint, each of the rib layer 5 and the partition 6A has a grating shape as seen in plan view and surrounds each of subpixels SP1, SP2 and SP3. The partition 6A functions as lines which apply common voltage to the upper electrodes UE1, UE2 and UE3.

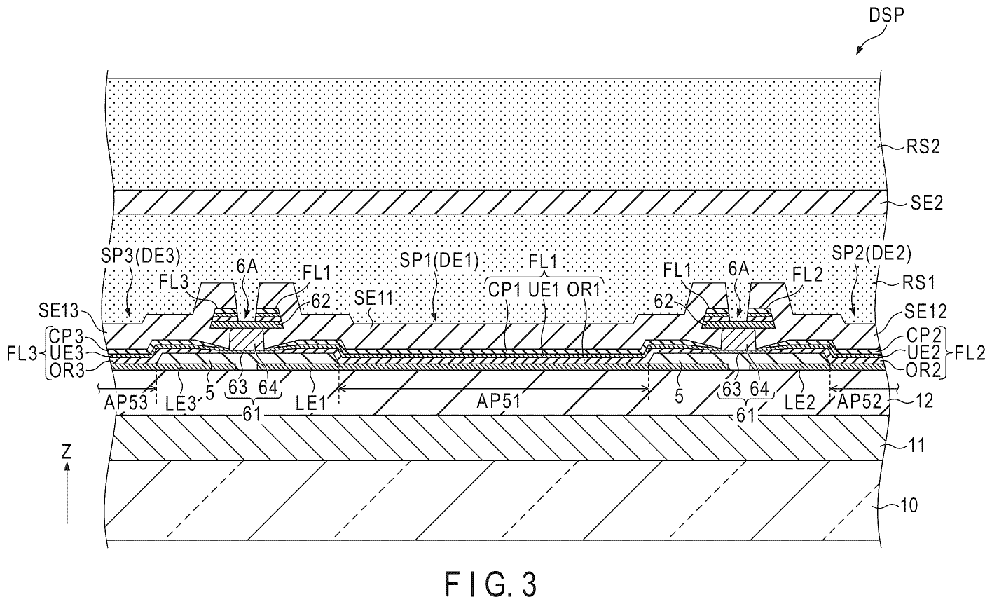

FIG. 3 is the schematic cross-sectional view of the display device DSP along the III-III line of FIG. 2. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP51. The upper electrode UE1 covers the organic layer OR1 and faces the lower electrode LE1. The organic layer OR2 covers the lower electrode LE2 through the pixel aperture AP52. The upper electrode UE2 covers the organic layer OR2 and faces the lower electrode LE2. The organic layer OR3 covers the lower electrode LE3 through the pixel aperture AP53. The upper electrode UE3 covers the organic layer OR3 and faces the lower electrode LE3. The upper electrodes UE1, UE2 and UE3 are in contact with the side surfaces of the lower portions 61 of the partition 6A.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6A (in other words, the portion which constitutes the display element DE1). Similarly, the stacked film FL2 is partly located on the upper portion 62. This portion is spaced apart from, of the stacked film FL2, the portion located around the partition 6A (in other words, the portion which constitutes the display element DE2). Further, the stacked film FL3 is partly located on the upper portion 62. This portion is spaced apart from, of the stacked film FL3, the portion located around the partition 6A (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6A around subpixel SP1. The sealing layer SE12 continuously covers the cap layer CP2 and the partition 6A around subpixel SP2. The sealing layer SE13 continuously covers the cap layer CP3 and the partition 6A around subpixel SP3.

In the example of FIG. 3, the stacked film FL1 and sealing layer SE11 located on the partition 6A between subpixels SP1 and SP2 are spaced apart from the stacked film FL2 and sealing layer SE12 located on this partition 6A. The stacked film FL1 and sealing layer SE11 located on the partition 6A between subpixels SP1 and SP3 are spaced apart from the stacked film FL3 and sealing layer SE13 located on this partition 6A.

The sealing layers (first sealing layers) SE11, SE12 and SE13 are covered with a resin layer (first resin layer) RS1. The resin layer RS1 is covered with a sealing layer (second sealing layer) SE2. The sealing layer SE2 is covered with a resin layer (second resin layer) RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (Siox) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6A comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6A. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

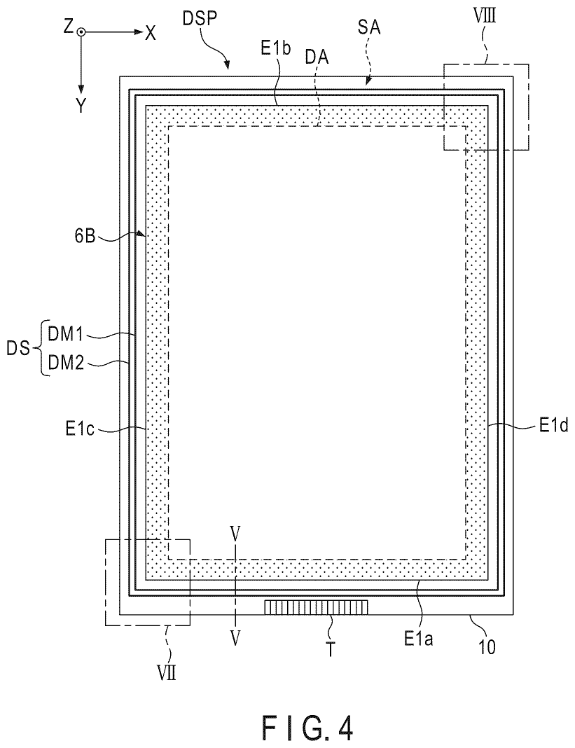

FIG. 4 is a schematic plan view of the display device DSP for explaining the structure of the surrounding area SA. The display device DSP further comprises a partition (second partition) 6B provided in the surrounding area SA. The partition 6B is formed by the same process as the partition 6A shown in FIG. 2 and FIG. 3 and has a structure similar to that of the partition 6A. In FIG. 4, a dotted pattern is added to an area corresponding to the partition 6B. The partition 6B surrounds the display area DA.

The partition 6B has end portions (first to fourth end portions) E1a, E1b, E1c and E1d. The end portion E1a is located between the display area DA and the terminal portion T and extends parallel to the X-direction. The end portion E1b is located on a side opposite to the end portion E1a across the intervening display area DA and extends parallel to the X-direction. The end portion E1c connects the left ends of the end portions E1a and E1b to each other in the figure, and extends parallel to the Y-direction. The end portion E1d connects the right ends of the end portions E1a and E1b to each other in the figure, and extends parallel to the Y-direction.

The display device DSP comprises a dam structure DS provided in the surrounding area SA. In the example of FIG. 4, the dam structure DS includes rectangular dam portions DM1 and DM2.

The dam portion DM1 surrounds the partition 6B. The dam portion DM2 surrounds the dam portion DM1. The dam portions DM1 and DM2 partly pass through the area located between the terminal portion T and the partition 6B.

It should be noted that the shape of the dam portion DM1 or DM2 is not limited to the example of FIG. 4. Further, the number of dam portions provided in the dam structure DS may be one or may be three or greater.

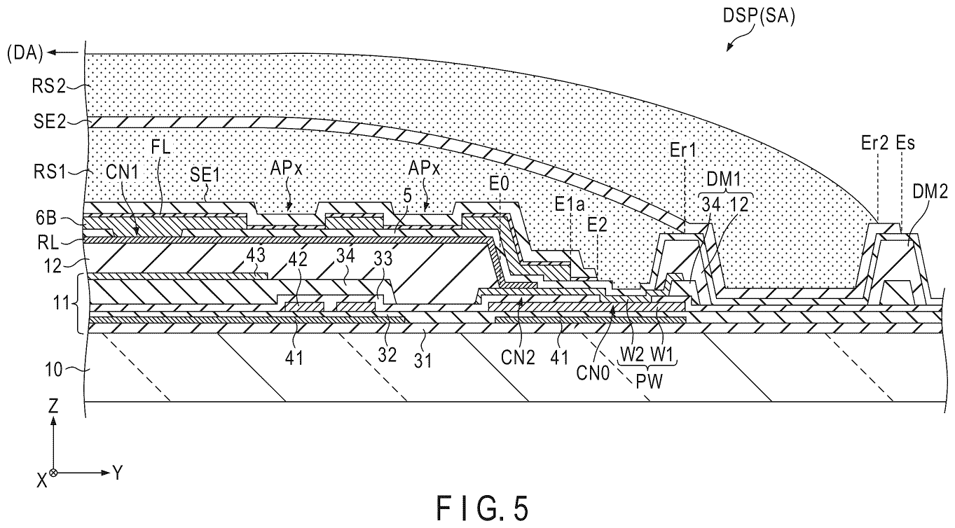

FIG. 5 is the schematic cross-sectional view of part of the surrounding area SA along the V-V line of FIG. 4. The sectional structure shown in this figure can be applied to any position of the surrounding area SA.

The circuit layer 11 shown in FIG. 3 has inorganic insulating layers 31, 32 and 33 each of which is formed of an inorganic insulating material, an organic insulating layer 34 formed of an organic insulating material, and metal layers 41, 42 and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

Both the dam portion DM1 and the dam portion DM2 protrude to the upper side of the substrate 10. In the example of FIG. 5, the dam portion DM1 consists of the organic insulating layers 12 and 34. Similarly, the dam portion DM2 consists of the organic insulating layers 12 and 34. In other words, in the embodiment, the dam portions DM1 and DM2 are formed of the same materials as the organic insulating layers 12 and 34 by the same process as the organic insulating layers 12 and 34.

The circuit layer 11 comprises a power supply line PW to which common voltage is applied. The power supply line PW is connected to the terminal portion T shown in FIG. 4. In the example of FIG. 5, the power supply line PW has a first line W1 consisting of the metal layer 42, and a second line W2 consisting of the metal layer 43. The first line W1 and the second line W2 are in contact with each other in a contact portion CN0 located between the end portion E0 of the organic insulating layer 12 and the dam portion DM1.

In the surrounding area SA, a conductive relay layer RL which connects the partition 6B and the power supply line PW to each other and the rib layer 5 are further provided. For example, the relay layer RL is formed of the same material by the same process as the lower electrodes LE1, LE2 and LE3 described above.

The relay layer RL is located on the display area DA side (the left side in the figure) relative to the dam portion DM1 and covers the organic insulating layer 12. The rib layer 5 continuously covers the relay layer RL and the dam portions DM1 and DM2. The end portion of the rib layer 5 is located on the external side relative to the dam portion DM2.

The partition 6B is provided on the rib layer 5. The rib layer 5 is open in a contact portion CN1 which overlaps the organic insulating layer 12 as seen in plan view. The partition 6B is in contact with the relay layer RL in the contact portion CN1.

The relay layer RL is in contact with the second line W2 of the power supply line PW in a contact portion CN2. The contact portion CN2 is located between the end portion E0 of the organic insulating layer 12 and the dam portion DM1 as seen in plan view.

The partition 6B is covered with a stacked film FL. The stacked film FL is covered with a sealing layer SE1. The stacked film FL is one of the stacked films FL1, FL2 and FL3 shown in FIG. 3. The sealing layer SE1 is one of the sealing layers SE11, SE12 and SE13 shown in FIG. 3.

In the example of FIG. 5, the end portion E2 of the stacked film FL and the sealing layer SE1 is located between the end portion E1a of the partition 6B and the dam portion DM1. The stacked film FL is divided by the end portion E1a. The sealing layer SE1 continuously covers the portions into which the stacked film FL1 is divided. As the stacked film FL is divided in this manner, the path of moisture intrusion through the stacked film FL can be blocked.

The resin layer RS1, sealing layer SE2 and resin layer RS2 shown in FIG. 3 are provided above the sealing layer SE1. The resin layer RS1 covers the sealing layer SE1 and the rib layer 5. The end portion E2 of the stacked film FL and the sealing layer SE1 is covered with the resin layer RS1. When the display device DSP is manufactured, the dam portion DM1 functions to dam up the resin layer RS1 before it is cured.

In the example of FIG. 5, the end portion Er1 of the resin layer RS1 is located above the dam portion DM1. However, the position of the end portion Er1 is not limited to this example.

The sealing layer SE2 covers the end portion Er1 of the resin layer RS1. The sealing layer SE2 is in contact with the rib layer 5 in an area located on the external side (the right side in the figure) relative to the end portion Er1. In the example of FIG. 5, the end portion Es of the sealing layer SE2 is located above the dam portion DM2. The resin layer RS1 is surrounded by the sealing layer SE1, the rib layer 5 and the sealing layer SE2. By this configuration, the moisture intrusion into the resin layer RS1 is prevented.

The resin layer RS2 covers the sealing layer SE2. When the display device DSP is manufactured, the dam portion DM2 functions to dam up the resin layer RS2 before it is cured. In the embodiment, the end portion Er2 of the resin layer RS2 is located between the end portion Er1 of the resin layer RS1 and the end portion Es of the sealing layer SE2. More specifically, the end portion Er2 is located above the dam portion DM2. It should be noted that the position of the end portion Er2 is not limited to the example of FIG. 5.

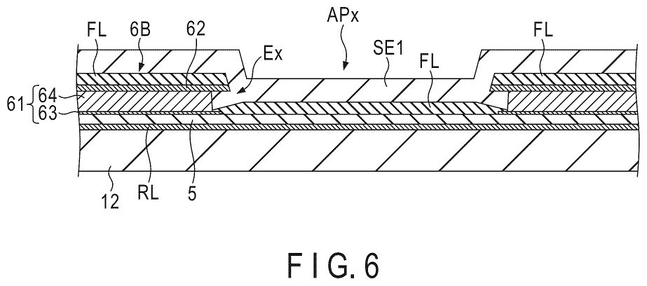

FIG. 6 is a schematic enlarged cross-sectional view of part of the partition 6B. The partition 6B includes lower and upper portions 61 and 62 which are similar to those of the partition 6A. Further, the lower portion 61 of the partition 6B includes a bottom layer 63 and a stem layer 64.

In this embodiment, the partition 6B comprises a plurality of apertures APx. In the edge portion Ex of the aperture APx, the upper portion 62 protrudes from the side surface of the stem layer 64. In other words, the edge portion Ex has an overhang shape in a manner similar to that of the partition 6A shown in FIG. 3. Each of the end portions E1a, E1b, E1c and E1d of the partition 6B shown in FIG. 4 similarly has an overhang shape.

The stacked film FL is divided by the edge portion Ex. The sealing layer SE1 continuously covers the portions into which the stacked film FL is divided.

Now, this specification explains the planar shape and the layout form of the apertures APx while looking at areas VII and VIII surrounded by the chained frames in FIG. 4.

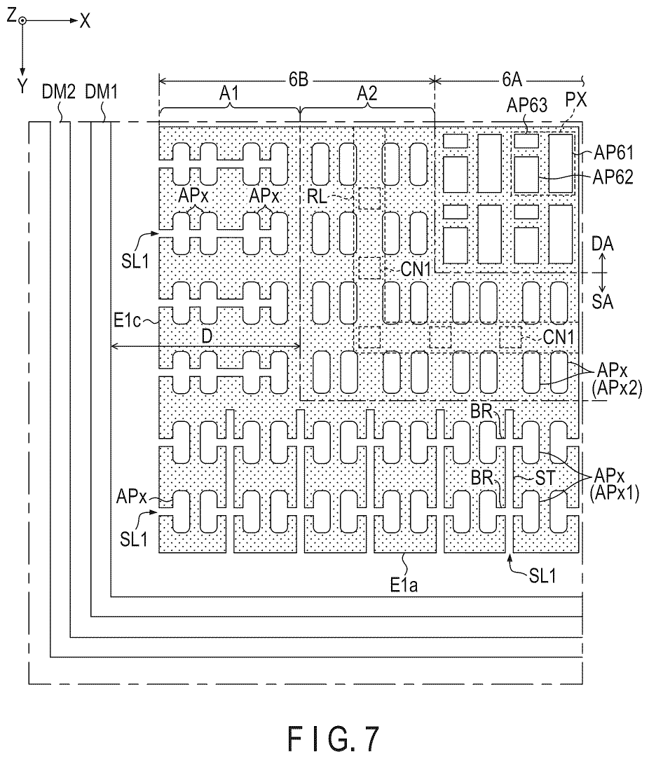

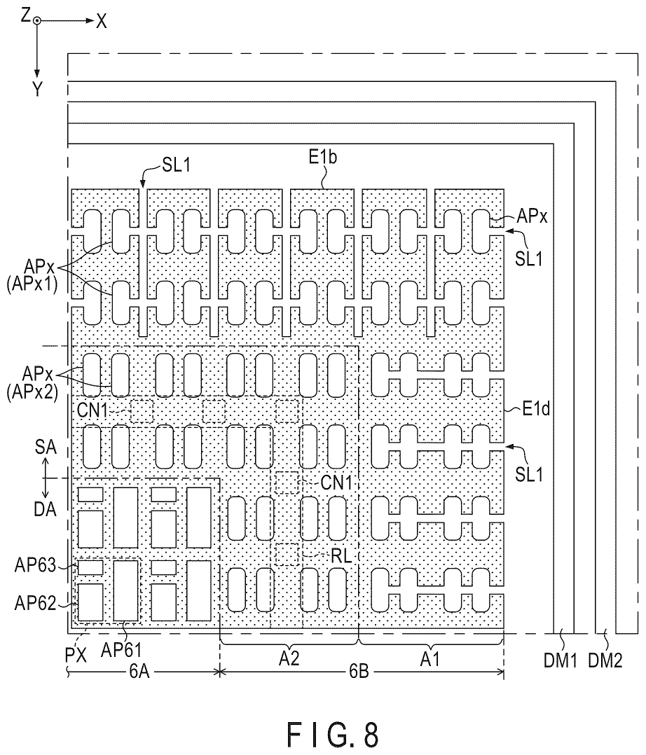

FIG. 7 is a schematic enlarged plan view of area VII. FIG. 8 is a schematic enlarged plan view of area VIII. In these figures, the partitions 6A and 6B, the dam portions DM1 and DM2, the relay layer RL and the contact portion CN1 are shown, and the other elements are omitted.

In FIG. 7 and FIG. 8, the portions indicated by the dotted pattern correspond to the partitions 6A and 6B. The partitions 6A and 6B are integrally formed. The partition 6A has the pixel apertures AP61, AP62 and AP63 described above. The partition 6B has the apertures APx described above.

Each aperture APx has an elongated shape. Specifically, each aperture APx has a shape in which the corner portions of a rectangle which is elongated in the Y-direction are rounded. For example, the width of each aperture APx in the Y-direction is two to three times the width of each aperture APx in the X-direction. It should be noted that the shapes of the apertures APx are not limited to this example. For example, each aperture APx may have a shape which is elongated in the X-direction.

In the examples of FIG. 7 and FIG. 8, two apertures APx which are arranged in the X-direction are provided close to each other. Further, the pairs of these apertures APx are arranged in the X-direction and the Y-direction. For example, the interval between the pairs of apertures APx in the X-direction and the Y-direction is the same as the interval of pixels PX in the X-direction and the Y-direction. In this configuration, the density of the apertures of the partitions 6A and 6B is uniformed in the display area DA and the surrounding area SA. This configuration can prevent variation in the progression of erosion in an X-Y plane when the base layers of the partitions 6A and 6B are etched in the manufacturing of the display device DSP.

The partition 6B further has a plurality of slits (first slits) SL1 which reach one of the end portions E1a, E1b, E1c and E1d. For example, each of these slits SL1 has a width which is less than the width in the short direction of each aperture APx (in the examples of FIG. 7 and FIG. 8, the X-direction).

Each slit SL1 is connected to at least one aperture APx. In the following explanation, each aperture APx connected to the slit SL1 is called an aperture (first aperture) APx1. Each independent aperture APx which is not connected to any slit SL1 is called an aperture (second aperture) APx2.

For example, each of the slits SL1 which are open in the end portion E1a in FIG. 7 and the slits SL1 which are open in the end portion E1b in FIG. 8 has a trunk portion ST which extends parallel to the Y-direction, and two branch portions BR which intersect with the trunk portion ST and extend in the X-direction. Further, the both end portions of each branch portion BR are connected to the long sides of the apertures APx1. In other words, each of these slits SL1 is connected to four apertures APx1.

The slits SL1 which are open in the end portion E1c in FIG. 7 and the slits SL1 which are open in the end portion E1d in FIG. 8 extend in the X-direction, and most of these slits are connected to the long sides of four apertures APx1. However, of the slits SL1 which are open in the end portion E1c, each of the slits SL located in the corner portion of the end portions E1a and E1c and the corner portion of the end portions E1b and E1d is connected to the long side of one aperture APx1.

It should be noted that the relationship between the slits SL1 and the apertures APx is not limited to the examples shown here. For example, a slit SL1 connected to two apertures APx1, a slit SL1 connected to three apertures APx1 or a slit SL1 connected to five or more apertures APx1 may be present.

Here, the first and second areas A1 and A2 of the partition 6B are defined as shown in FIG. 7 and FIG. 8. The first area A1 is a portion along the end portions E1a, E1b, E1c and E1d of the partition 6B and includes a plurality of slits SL1 and a plurality of apertures APx1 connected to these slits SL1. The second area A2 is a portion located between the first area A1 and the display area DA and includes a plurality of apertures APx2 which are not connected to any slit SL1. The second area A2 surrounds the display area DA.

The boundary between the first area A1 and the second area A2 is located in the range of, for example, distance D from the dam portion DM1. Distance D may be determined in the range of, for example, 100 to 300 μm. For example, distance D is 200 μm.

The second area A2 overlaps the relay layer RL shown in FIG. 5 as seen in plan view. For example, the relay layer RL surrounds the display area DA. The contact portions CN1 of the partition 6B and the relay layer RL are dispersed at several positions of the second area A2. In the examples of FIG. 7 and FIG. 8, the contact portions CN1 are provided at positions which do not overlap the apertures APx2 between the end portion E1a and the display area DA, between the end portion E1b and the display area DA, between the end portion E1c and the display area DA and between the end portion E1d and the display area DA.

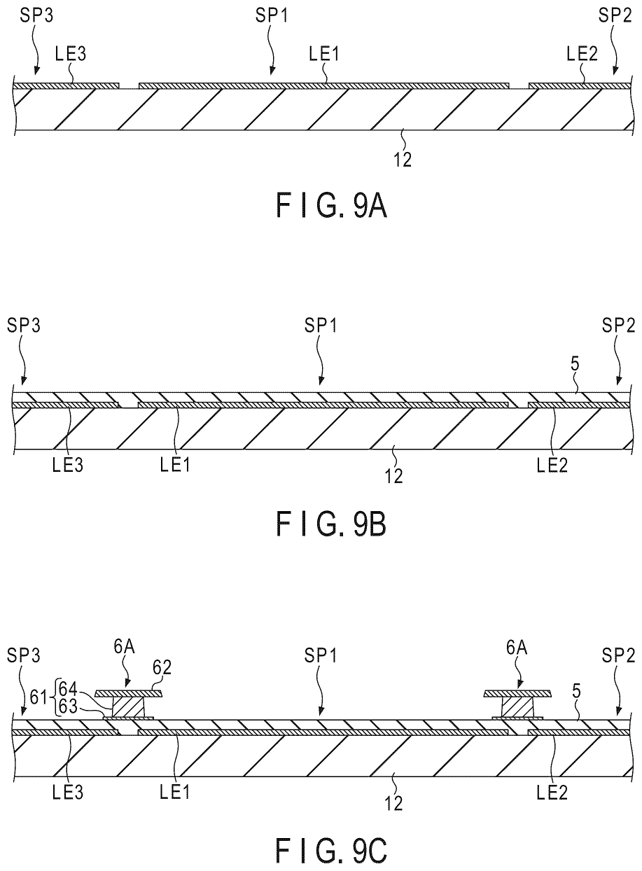

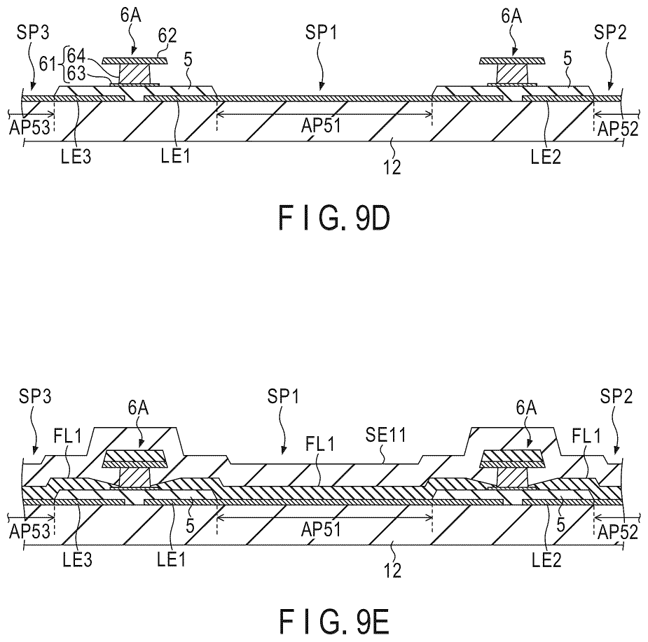

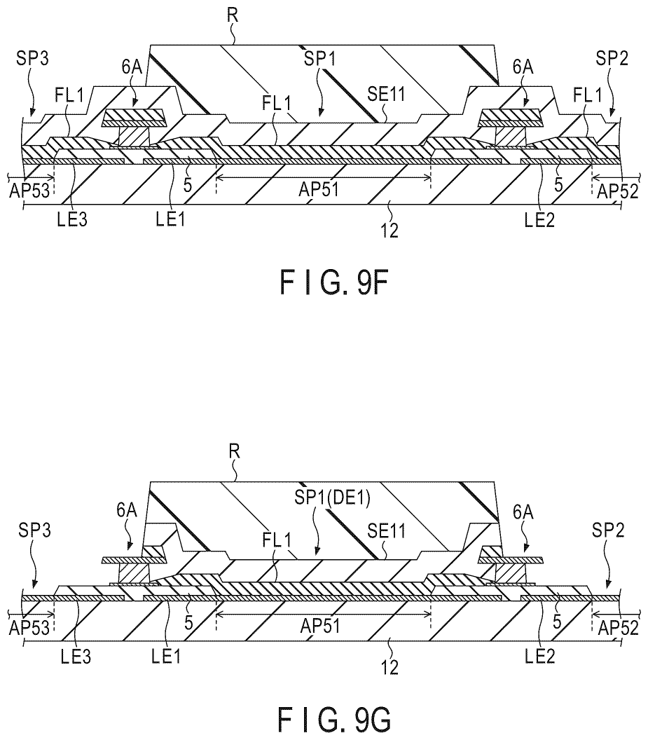

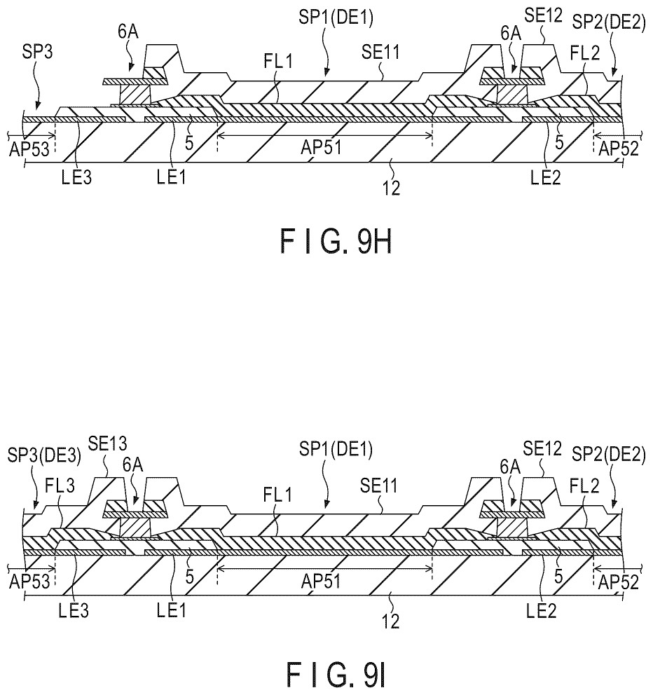

Now, this specification explains an example of the manufacturing method of the display device DSP. Each of FIG. 9A to FIG. 9I is a schematic cross-sectional view showing the manufacturing process of the display device DSP. In FIG. 9A to FIG. 9I, the display area DA is mainly looked at, and the elements located under the organic insulating layer 12 are omitted.

To form the display device DSP, first, the circuit layer 11 and the organic insulating layer 12 are formed on the substrate 10. Subsequently, as shown in FIG. 9A, the lower electrodes LE1, LE2 and LE3 are formed on the organic insulating layer 12.

Subsequently, as shown in FIG. 9B, the rib layer 5 which covers the organic insulating layer 12 and the lower electrodes LE1, LE2 and LE3 is formed. For example, chemical vapor deposition (CVD) can be used for the formation of the rib layer 5.

Further, as shown in FIG. 9C, the partition 6A is formed on the rib layer 5. Specifically, first, the base layers of the bottom layer 63, the stem layer 64 and the upper portion 62 are formed, and these layers are patterned by etching. The partition 6B shown in FIG. 4 to FIG. 8 is formed by the same process as the partition 6A.

After the formation of the partitions 6A and 6B, as shown in FIG. 9D, the pixel apertures AP51, AP52 and AP53 are formed in the rib layer 5 by dry etching. In addition to this process, a plurality of dry etching processes are performed for the rib layer 5. For example, these dry etching processes include etching for forming the apertures of the contact portions CN1 in the rib layer 5 in the surrounding area SA.

After the formation of the rib layer 5 and the partitions 6A and 6B, a process for forming the display elements DE1, DE2 and DE3 is performed. In the present embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 9E, the stacked film FL1 and the sealing layer SE11 are formed. The stacked film FL1 includes, as shown in FIG. 3, the organic layer OR1 which is in contact with the lower electrode LE1 through the pixel aperture AP51, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE11 is formed by CVD.

The stacked film FL1 and the sealing layer SE11 are formed in the surrounding area SA as well as the display area DA. The stacked film FL1 is divided into a plurality of portions by the partitions 6A and 6B having an overhang shape. The sealing layer SE11 continuously covers the portions into which the stacked film FL1 is divided, and the partitions 6A and 6B.

Subsequently, the stacked film FL1 and the sealing layer SE11 are patterned. In this patterning, as shown in FIG. 9F, a resist R is provided on the sealing layer SE11. The resist R covers subpixel SP1 and part of the partition 6A around the subpixel.

Subsequently, as shown in FIG. 9G, the portions of the stacked film FL1 and the sealing layer SE11 exposed from the resist R are removed by etching using the resist R as a mask. In other words, of the stacked film FL1 and the sealing layer SE11, the portions which overlap the lower electrode LE1 remain, and the other portions are removed. By this process, the display element DE1 is formed in subpixel SP1. This etching could include wet etching and dry etching processes which are performed in order for the sealing layer SE11, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE12 are formed in the entire display area DA and surrounding area SA. The stacked film FL2 includes, as shown in FIG. 3, the organic layer OR2 which is in contact with the lower electrode LE2 through the pixel aperture AP52, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partitions 6A and 6B having an overhang shape. The sealing layer SE12 continuously covers the portions into which the stacked film FL2 is divided, and the partitions 6A and 6B. By patterning these stacked film FL2 and sealing layer SE12, the display element DE2 is formed in subpixel SP2 as shown in FIG. 9H.

The display element DE3 is formed by a procedure similar to the procedures of the display elements DE1 and DE2. Specifically, when the display element DE3 is formed, the stacked film FL3 and the sealing layer SE13 are formed in the entire display area DA and surrounding area SA. The stacked film FL3 includes, as shown in FIG. 3, the organic layer OR3 which is in contact with the lower electrode LE3 through the pixel aperture AP53, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE13 is formed by CVD. The stacked film FL3 is divided into a plurality of portions by the partitions 6A and 6B having an overhang shape. The sealing layer SE13 continuously covers the portions into which the stacked film FL3 is divided, and the partitions 6A and 6B. By patterning these stacked film FL3 and sealing layer SE13, the display element DE3 is formed in subpixel SP3 as shown in FIG. 9I.

After the display elements DE1, DE2 and DE3 are formed, the resin layer RS1, sealing layer SE2 and resin layer RS2 shown in FIG. 3 are formed in order.

The stacked film FL shown in FIG. 5 and FIG. 6 is, for example, the stacked film FL1 which is formed firstly among the stacked films FL1, FL2 and FL3. Similarly, the sealing layer SE1 is the sealing layer SE11 which is formed firstly among the sealing layers SE11, SE12 and SE13. When the sealing layer SE11 which is formed firstly is left in the surrounding area SA in this manner, the surrounding area SA can be protected from etching which is performed at the time of forming the display elements DE2 and DE3.

As another example, the stacked film FL may be the stacked film FL3 which is formed lastly among the stacked films FL1, FL2 and FL3. Similarly, the sealing layer SE1 may be the sealing layer SE13 which is formed lastly among the sealing layers SE11, SE12 and SE13.

The stacked films FL1, FL2 and FL3 formed by vapor deposition may have poor adherence to the base. Therefore, the stacked films FL1, FL2 and FL3 and the sealing layers SE11, SE12 and SE13 which cover these stacked films may be removed from the base when the display device DSP is manufactured.

This removal easily occurs in a case where the stacked films FL1, FL2 and FL3 are continuously formed in a wide range. In the display area DA, the stacked films FL1, FL2 and FL3 are divided into pieces by the partition 6A. Thus, the removal described above is prevented.

Further, in this embodiment, the partition 6B having the apertures APx is provided in the surrounding area SA. By this configuration, the stacked films FL1, FL2 and FL3 are divided into pieces in the surrounding area SA as well, and the removal described above is prevented.

Moreover, for example, the effect explained below can be obtained from the configuration shown in FIG. 7 and FIG. 8.

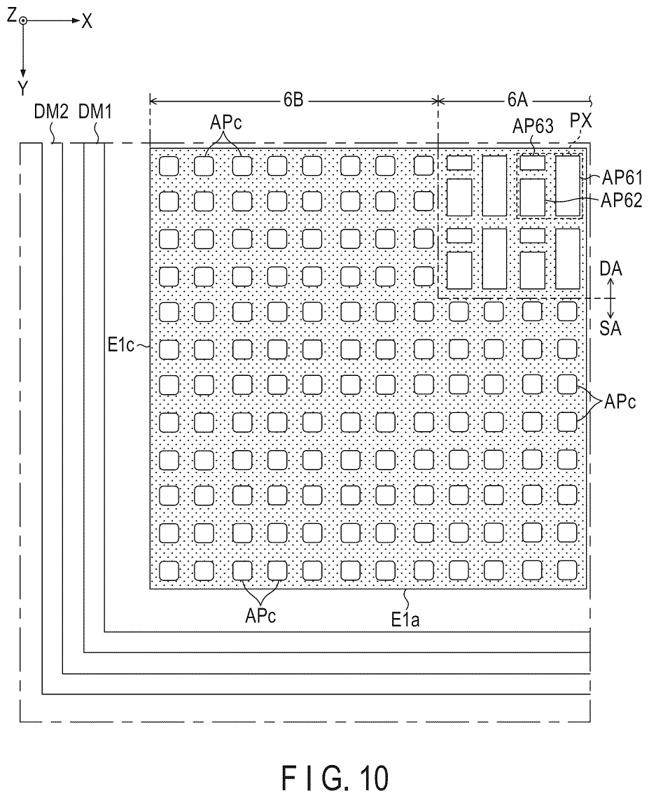

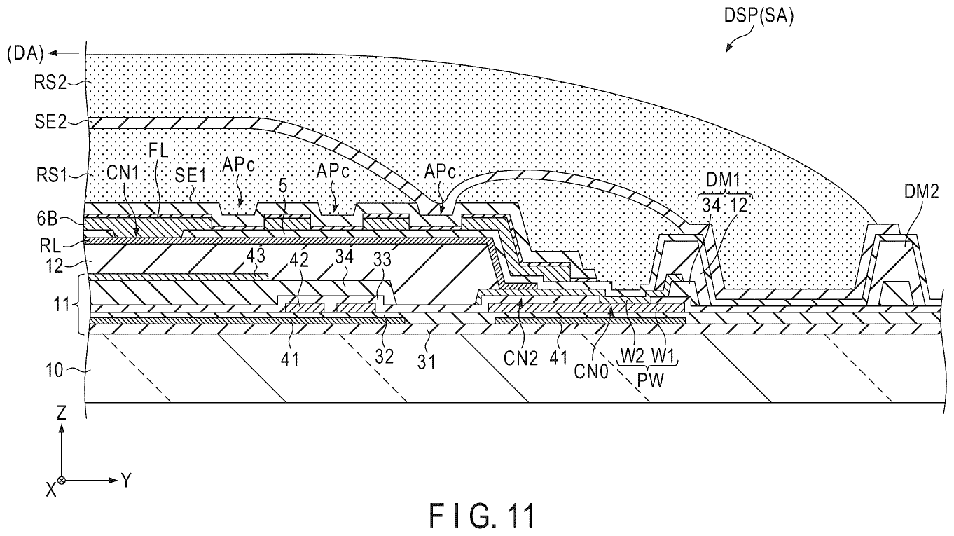

FIG. 10 is a schematic plan view of the surrounding area SA according to a comparative example of the embodiment. FIG. 11 is a schematic cross-sectional view of the surrounding area SA according to the comparative example. As shown in FIG. 10, in the comparative example, a large number of apertures APc which are smaller than the apertures APx shown in FIG. 7 and FIG. 8 are provided in the partition 6B. Each of these apertures APc has a shape in which the corner portions of a square are rounded. The width of each aperture APc in the X-direction is equal to that of each aperture APc in the Y-direction.

In a case where the small apertures APc are provided in the partition 6B in this manner, when the resin layer RS1 is formed, the resin layer RS1 before cured may be repelled by the projections and depressions of the sealing layer SE1 generated by the apertures APc. FIG. 11 shows a state in which the resin layer RS1 is repelled near the leftmost aperture APc in the figure and cured as it is.

The resin layer RS1 functions to planarize the base of the sealing layer SE2. If the resin layer RS1 is cured in the repelled state, the shape of the sealing layer SE2 formed on the resin layer RS1 becomes defective, and the path of moisture intrusion into the inside of the display device DSP could be formed.

To the contrary, in the embodiment, each aperture APx has a shape which is elongated in the Y-direction as shown in FIG. 7 and FIG. 8. In this case, for example, when it is assumed that the widths of each aperture APx and each aperture APc in the X-direction are substantially equal to each other, the width of each aperture APx in the Y-direction is greater than that of each aperture APc in the Y-direction. Therefore, the repelling of the resin layer RS1 caused by the apertures APx does not easily occur.

The resin layer RS1 is applied by, for example, an ink-jet method. In this case, if the moving direction (application direction) relative to the substrate of a head which discharges the resin layer RS1 is coincident with the elongated direction of the apertures APx, the repelling of the resin layer RS1 caused by the apertures APx is further satisfactorily prevented. Therefore, when the apertures APx are elongated in the Y-direction as shown in FIG. 7 and FIG. 8, it is preferable that the application direction should be also parallel to the Y-direction. As another example, each aperture APx may have a shape which is elongated in the X-direction, and the application direction may be parallel to the X-direction.

As the resin layer RS1 is thin near the end portions E1a, E1b, E1c and E1d, the repelling described above easily occurs. In this regard, in the examples of FIG. 7 and FIG. 8, the slits SL1 are provided in the first area A1 along the end portions E1a, E1b, E1c and E1d of the partition 6B, and the apertures APx1 are connected to these slits SL1. In this configuration, the inside of each depressed portion of the sealing layer SE1 generated by the apertures APx is easily filled with the resin layer RS1 before cured through the slits SL1. For this reason, the repelling described above can be effectively prevented.

For example, the resin layer RS1 becomes easily thin in the range in which distance D shown in FIG. 7 is less than 100 μm. Further, if the slits SL1 are formed to the extent of the vicinity of the display area DA, the resistance of the second area A2 which is responsible for power supply from the relay layer RL may be increased. Therefore, distance D should be preferably determined in the range of 100 to 300 μm as described above.

### Second Embodiment

A second embodiment is explained. Regarding a display device DSP, configurations which are not referred to in this embodiment are the same as the first embodiment.

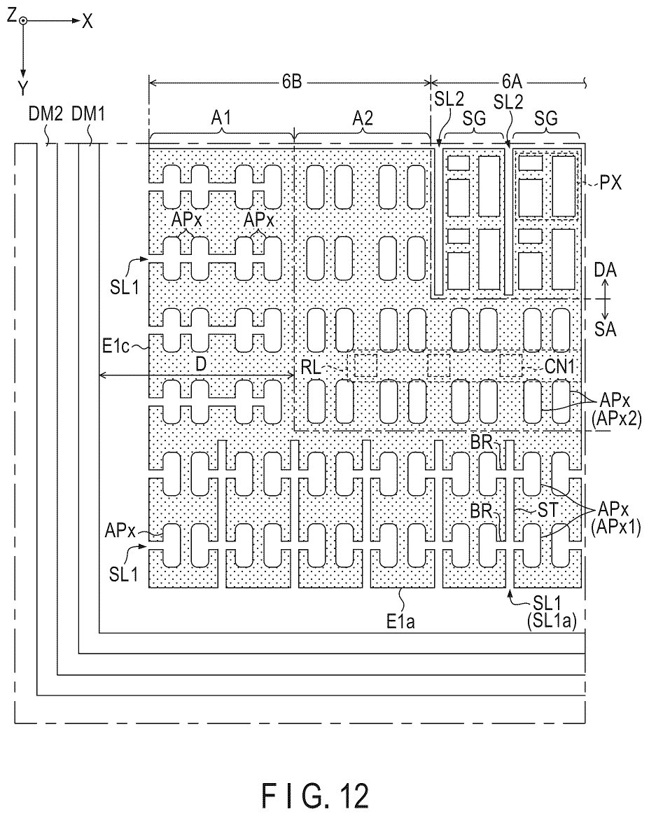

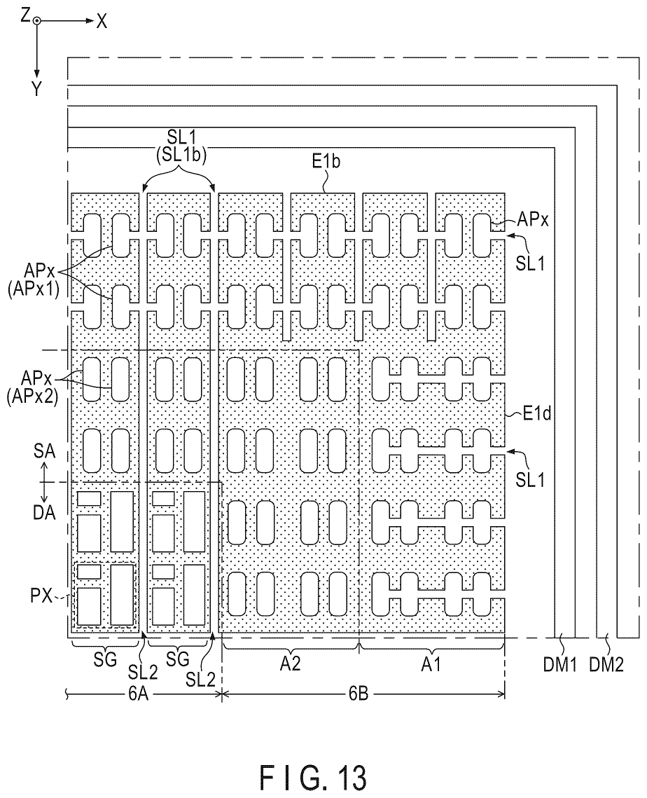

FIG. 12 and FIG. 13 are schematic enlarged plan views of a surrounding area SA according to the second embodiment. FIG. 12 and FIG. 13 show areas similar to those of FIG. 7 and FIG. 8, respectively.

In this embodiment, a partition 6A formed in a display area DA is divided into a plurality of segments SG by a plurality of slits (second slits) SL2. Each slit SL2 extends in a Y-direction. In the examples of FIG. 12 and FIG. 13, each segment SG consists of a column of pixels PX arranged in the Y-direction. The configuration is not limited to this example. Each segment SG may consist of a plurality of columns of pixels PX.

In a manner similar to that of the first embodiment, a plurality of slits SL1 are provided in a partition 6B. Hereinafter, each slit SL1 which reaches an end portion E1a as shown in FIG. 12 is called a slit (third slit) SL1a. Each slit SL1 which reaches an end portion E1b as shown in FIG. 13 is called a slit (fourth slit) SL1b.

As shown in FIG. 12, each slit SL1a is provided in a first area A1 and spaced apart from each slit SL2. To the contrary, as shown in FIG. 13, some of the slits SL1b intersect with the first area A1 and a second area A2 and are connected to the slits SL2 of the display area DA. The slits SL1b and SL2 connected to each other constitute a continuous slit provided in a conductive layer including the partitions 6A and 6B.

In the examples of FIG. 12 and FIG. 13, a relay layer RL and contact portions CN1 are provided between the display area DA and the end portion E1a. To the contrary, the relay layer RL or the contact portions CN1 are not provided between the display area DA and the end portion E1b, E1c or E1d.

In an electronic device on which the display device DSP is mounted, in some cases, an antenna for near field communication (NFC) may be provided in the back of the display device DSP. In this case, in a structure in which the partition 6A having a grating shape is provided in the display area DA like the first embodiment, and further, the circumference is surrounded by the second area of the partition 6B, the conductive layer consisting of the partitions 6A and 6B may be a cause to decrease the sensitivity of wireless communication by the antenna described above.

Specifically, eddy current is generated in the conductive layer described above by a magnetic field formed by the antenna. By this eddy current, a magnetic field having a direction which negates the above magnetic field is formed, and the signal strength is attenuated. Thus, when wireless communication is performed via the display device DSP, the communication sensitivity could be decreased.

To the contrary, in this embodiment, the conductive layer described above is divided from the end portion E1b by the slits SL1b and SL2. This configuration can prevent the generation of the eddy current described above and increase the communication sensitivity of near field communication. In addition to the above explanation, effects similar to those of the first embodiment are obtained from the display device DSP of the second embodiment.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a substrate having a display area which displays an image, and a surrounding area around the display area;
a plurality of display elements in the display area, each of the display elements including a lower electrode, an upper electrode above the lower electrode, and an organic layer between the lower electrode and the upper electrode and emitting light based on application of voltage;
a first partition provided in the display area and provided between the adjacent display elements; and
a second partition provided in the surrounding area and connected to the first partition, wherein
each of the first partition and the second partition includes a conductive lower portion and an upper portion which has an end portion protruding from a side surface of the lower portion, and
the second partition has a plurality of apertures each of which has an elongated shape.

2. The display device of claim 1, wherein
the second partition surrounds the display area.

3. The display device of claim 2, wherein
the second partition has a plurality of first slits which reach an end portion of the second partition, and
the apertures include a plurality of first apertures each of which is connected to one of the first slits.

4. The display device of claim 3, wherein
the first slits are connected to long sides of the first apertures.

5. The display device of claim 3, wherein
the apertures further include a plurality of second apertures which are not connected to the first slits and are independent from each other.

6. The display device of claim 5, wherein
the second partition has a first area along the end portion of the second partition, and a second area located between the first area and the display area,
the first apertures and the first slits are provided in the first area, and
the second apertures are provided in the second area.

7. The display device of claim 6, further comprising:
a terminal portion provided in the surrounding area;
a power supply line connected to the terminal portion; and
a relay layer connected to the power supply line and the second partition, wherein
the relay layer is formed of a same material as the lower electrode in a same layer as the lower electrode.

8. The display device of claim 7, wherein
the relay layer and the second partition are connected to each other via a contact portion located in the second area.

9. The display device of claim 8, wherein
the second area and the relay layer surround the display area.

10. The display device of claim 3, wherein
the first partition is divided into a plurality of segments by a second slit located in the display area.

11. The display device of claim 10, wherein
the second partition has a first end portion, and a second end portion located on a side opposite to the first end portion across the intervening display area,
the first slits include a third slit which reaches the first end portion and a fourth slit which reaches the second end portion, and
the second slit is spaced apart from the third slit and is connected to the fourth slit.

12. The display device of claim 1, further comprising a dam portion which is provided in the surrounding area and surrounds the second partition.

13. The display device of claim 12, further comprising a rib layer which is formed of an inorganic insulating material and is located under the first partition and the second partition, wherein
the rib layer covers the dam portion.

14. The display device of claim 13, further comprising a first sealing layer which covers a stacked film including the organic layer and the upper electrode, wherein
each of the stacked film and the first sealing layer is partly provided surrounding area.

15. The display device of claim 14, wherein
the stacked film is divided by an edge portion of the apertures.

16. The display device of claim 14, wherein
an end portion of each of the stacked film and the first sealing layer is located between an end portion of the second partition and the dam portion.

17. The display device of claim 16, wherein
the stacked film is divided by the end portion of the second partition.

18. The display device of claim 14, further comprising a first resin layer which covers the first sealing layer.

19. The display device of claim 18, further comprising a second sealing layer which covers the first resin layer, wherein
the second sealing layer is in contact with the rib layer in an area located on an external side relative to an end portion of the first resin layer.

20. The display device of claim 19, further comprising a second resin layer which covers the second sealing layer.
